(19) United States
(12) Patent Application Publication
(10) Pub. No.: US 2007/0215901 A1
(43) Pub. Date: Sep. 20, 2007

(54) Group III-V nitride-based semiconductor substrate and method of fabricating the same

(75) Inventor: Masatomo Shibata, Tsuchiura (JP)

Correspondence Address: FOLEY AND LARDNER LLP;SUITE 500, 3000 K STREET NW, WASHINGTON, DC, 20007, US

(73) Assignee: HITACHI CABLE, LTD.

(21) Appl. No.: 11/508,846

(22) Filed: Aug. 24, 2006

(30) Foreign Application Priority Data
Mar. 15, 2006 (JP) 2006-071724

(51) Int. Cl. H01L 21/337; H01L 31/00

(52) U.S. Cl. 257/189

(57) ABSTRACT

A group III-V nitride-based semiconductor substrate has: a first layer made of GaN single crystal; and a second layer formed on the first layer, the second layer made of group III-V nitride-based semiconductor single crystal represented by AlₓGa₁₋ₓN, where 0<x≦1, wherein a top surface and a back surface of the substrate are flattened.

The present application is based on Japanese patent application No. 2006-071724, the entire contents of which are incorporated herein by reference.

### BACKGROUND OF THE INVENTION

1. Field of the Invention

This invention relates to a group III-V nitride-based semiconductor substrate and a method of fabricating the same. In particular, this invention relates to a group III-V nitride-based semiconductor substrate that can be lattice-matched to an epitaxial growth layer to provide a group III-V nitride-based device with reduced strain or defect, and a method of fabricating the substrate with a good reproducibility and at a low cost.

2. Description of the Related Art

Group III-V nitride-based compound semiconductors such as gallium nitride (GaN), indium gallium nitride (InGaN) and aluminum gallium nitride (GaAlN) are used to fabricate a short-wavelength light emitting device, especially, blue light emitting diode (LED) since they have a wide bandgap and are of direct transition type in interband transition. Recently, a ultraviolet LED with a further short wavelength and a white LED with a phosphor combined with such an LED are in practical use. Furthermore, the group III-V nitride-based compound semiconductors have applied to electronic devices and power devices since they have a good heat resistance and environment resistance.

In fabricating a semiconductor device, an underlying substrate is generally used which has the same lattice constant or linear expansion coefficient as a crystal to be grown on the substrate, so as to conduct the homo-epitaxial growth. For example, a GaAs single crystal substrate is used to conduct the epitaxial growth of GaAs, AlGaAs.

However, for group III-V nitride-based semiconductor crystals, no group III-V nitride-based semiconductor substrate with a practical size and characteristics has been obtained thus far. Therefore, most of nitride-based LED's developed are fabricated by using the hetero-epitaxial growth where group III-V nitride-based semiconductor crystals are grown on a sapphire substrate with a near lattice constant by MOVPE (metalorganic vapor phase epitaxy). Many problems arise from the hetero-growth.

For example, due to the difference in linear expansion coefficient between the sapphire substrate and GaN, a problem has occurred that the substrate after the epitaxial growth is warped significantly. This causes a reduction in yield since the substrate may crack during the photolithography or chip fabrication process after the epitaxial growth.

Further, since the lattice constant of the sapphire substrate is different from the GaN, a buffer layer needs to be deposited thereon at lower temperature than the proper crystal growth temperature before growing the nitride single crystal. This is a factor to increase the time required for the crystal growth. Furthermore, in case of the growth on the sapphire substrate, dislocations are generated as many as 10⁸ to 10⁹/cm⁻² in the GaN epi-layer due to the difference in lattice constant between the sapphire substrate and the GaN. The dislocation is a factor to lower the output and reliability of LED. Although in the conventional blue LED's the dislocation is not so much questioned, the influence of the dislocation on the device characteristics is assumed to increase hereafter according as the output of LED is further increased or as the emission wavelength thereof is shortened to develop the ultraviolet LED. Therefore, some measure is needed to reduce the dislocation.

In order to solve these problems, a self-standing substrate of GaN single crystal has been developed in recent years. The GaN self-standing substrate is produced by, e.g., ELO (epitaxial lateral overgrowth), where a mask with openings is formed on the underlying substrate (=sapphire substrate), and then the lateral growth is conducted through the openings to obtain GaN with a reduced dislocation, and after forming the GaN layer on the sapphire substrate, the sapphire substrate is removed by etching to obtain the GaN self-standing substrate (e.g., JP-A-11-251253).

As a progress of the ELO, FIELO (facet-initiated epitaxial lateral overgrowth) has been developed (e.g., Akira Usui et al., “Thick GaN Epitaxial Growth with Low Dislocation Density by Hydride Vapor Phase Epitaxy”, Jpn. J. Appl. Phys. Vol. 36(1997), pp. L899-902). The FIELO is in common with the ELO on the point that the selective growth is conducted by using the silicon dioxide mask, but it is different from the ELO on the point that a facet is formed at the mask opening during the selective growth. By forming the facet, the propagation direction of dislocation is changed so that the threading dislocation reaching the top surface of the epitaxial growth layer can be reduced. When a thick GaN layer is grown by using the FIELO on an underlying substrate such as sapphire and then the underlying substrate is removed, the GaN self-standing substrate with relatively few defects can be obtained.

The other methods for obtaining a low-dislocation GaN self-standing substrate include DEEP (Dislocation Elimination by the Epi-growth with inverted-Pyramidal pits: e.g., Kensaku Motoki et al., “Preparation of Large Freestanding GaN Substrates by Hydride Vapor Phase Epitaxy Using GaAs as a Starting Substrate”, Jpn. J. Appl. Phys. Vol. 40(2001) pp. L140-L143, and JP-A-2003-165799). The DEEP is conducted such that GaN is grown on a GaAs substrate, which is removable by etching, by using a SiN patterning mask while intentionally forming pits surrounded by facets on the surface of crystal, accumulating dislocations at the bottom of pits to allow regions other than pits to have a low dislocation density.

Further, the other methods for obtaining a low-dislocation GaN self-standing substrate include the method that a GaN layer is formed on a sapphire C-face ((0001) facet) substrate, a titanium film is formed thereon, the substrate is then subjected to heat treatment in an atmosphere of hydrogen gas or hydrogen-containing compound gas to form voids in the GaN layer, and a GaN semiconductor layer is formed on the GaN layer e.g., JP-A-2003-178984).

The GaN self-standing substrate obtained by using the ELO or DEEP etc., where the GaN film is grown on the hetero-substrate by HVPE and then the GaN layer is separated from the underlying substrate, is used mainly for the development of laser diode (LD) which requires especially a low-dislocation crystal. However, recently, it is also used for the LED substrate.

In fabricating a group III-V nitride-based light emitting device by using the GaN self-standing substrate, an AlGaN layer is generally formed as a cladding layer on the GaN self-standing substrate. Therefore, if the underlying substrate is of AlGaN, the epitaxial growth can be conducted with a further reduced lattice mismatch, i.e., reduced strain.

Therefore, the growth of Al-containing group III-V nitride-based semiconductor crystal has been researched by using HVPE which is employed to grow the GaN substrate (e.g., Andrey Nikolaev et al., “AlN Wafers Fabricated by Hydride Vapor Phase Epitaxy”, MRS Internet J. Nitride Semicond. Res. Volume 5S1 Published 2000, W6.5., and Y. Kumagai et al., “Hydride vapor phase epitaxy of AlN: the rmodynamic analysis of aluminum source and its application to growth”, Phys. Stat. Sol. (c), Vol. 0, No. 7, 2003, pp. 2498-2501).

Further, a GaN stacked substrate is known in which a Si—Al_{0.05}Ga_{0.95}N layer is grown about 10 μm on a GaN substrate (JP-A-2005-191306), and an AlGaN-based composite substrate is known in which an Al_{0.15}Ga_{0.85}N upper substrate is grown 300 to 400 μm on a GaN lower substrate (JP-A-2005-277015).

However, when the Al-containing group III-V nitride-based semiconductor crystal is grown by HVPE as disclosed in Andrey Nikolaev et al. and Y. Kumagai et al., aluminum chloride as a raw material may react with a quartz member composing the reactor depending on the grow conditions to corrode the member. Thus, when a thick film of the Al-containing group III-V nitride-based semiconductor is needed to grow, the quartz member will be corroded so much. Therefore, the quartz member needs to be replaced frequently, the manufacturing cost will be increased, and the quartz member may be broken during the crystal growth.

In addition, since AlGaN is a mixed crystal of three elements and it is, therefore, difficult to control the composition of AlGaN, the technique for producing a high-quality AlGaN single-crystal self-standing substrate with a good reproducibility is not realized at present.

On the other hand, when the AlGaN is in a separate process formed on the GaN substrate made previously as disclosed in JP-A-2005-191306 and JP-A-2005-277015, native oxide film will be generated since the GaN substrate is once exposed into the air, or the growth surface may be not clean due to a contamination during the handling. Further, since the GaN surface is subjected to a rising and falling temperature cycle, it may be denatured by heat. As a result, a layer containing many defects may be generated at the GaN/AlGaN interface, and a number of cracks may be generated in the AlGaN crystal layer.

### SUMMARY OF THE INVENTION

It is an object of the invention to provide a group III-V nitride-based semiconductor substrate that can be lattice-matched to an epitaxial growth layer to provide a group III-V nitride-based device with reduced strain or defect, and a method of fabricating the substrate with a good reproducibility and at a low cost.

(1) According to one aspect of the invention, a group III-V nitride-based semiconductor substrate comprises:

a first layer comprising GaN single crystal; and

a second layer formed on the first layer, the second layer comprising group III-V nitride-based semiconductor single crystal represented by AlₓGa₁₋ₓN, where 0<x≦1,

wherein a top surface and a back surface of the substrate are flattened.

In the above invention (1), the following modifications and changes can be made.

(i) The second layer comprises the group III-V nitride-based semiconductor single crystal represented by AlₓGa₁₋ₓN, where 0<x≦1, whose Al ratio increasing continuously from an interface of the first layer and the second layer.

(ii) The substrate is in circular form with a diameter of not less than 50 mm and a thickness of not less than 200 μm.

(iii) The substrate comprises a dislocation density of not more than 1×10⁸ cm⁻² on its surface.

(iv) The AlₓGa₁₋ₓN layer, where 0<x≦1, comprises a thickness of not less than 100 nm.

(v) The AlₓGa₁₋ₓN layer, where 0<x≦1, comprises a thickness of not less than 100 nm and not more than 100 μm.

(2) According to another aspect of the invention, a method of making a group III-V nitride-based semiconductor substrate comprises the steps of:

growing a group III-V nitride-based semiconductor film on a hetero-substrate and then depositing a metal film thereon;

heating the hetero-substrate with the metal film in an atmosphere containing hydrogen gas or hydride gas to form a void in the group III-V nitride-based semiconductor film;

growing a first layer comprising a GaN single crystal thereon;

further growing thereon a second layer comprising a group III-V nitride-based semiconductor single crystal represented by AlₓGa₁₋ₓN, where 0<x≦1;

removing the hetero-substrate while leaving the first layer and the second layer to provide the group III-V nitride-based semiconductor substrate; and

flattening a top surface and a back surface of the substrate.

In the above invention (2), the following modifications and changes can be made.

(vi) The first layer and the second layer are continuously grown in a same reactor.

(vii) The first layer and the second layer are grown by HVPE.

### ADVANTAGES OF THE INVENTION

Since the group III-V nitride-based semiconductor substrate is lattice-matched to an epitaxial growth layer grown thereon, a group III-V nitride-based device with reduced strain or defect can be provided by using the substrate.

Also, by using the methods of the invention, the group III-V nitride-based semiconductor substrate to be lattice-matched to an epitaxial growth layer grown thereon can be easy fabricated with a good reproducibility.

### BRIEF DESCRIPTION OF THE DRAWINGS

The preferred embodiments according to the invention will be explained below referring to the drawings, wherein:

FIG. 1 is a cross sectional view showing a composite self-standing substrate in a preferred embodiment according to the invention;

FIG. 2 is a schematic diagram showing an HVPE reactor to be used in the preferred embodiments of the invention;

FIGS. 3A to 3F are schematic cross sectional views showing a method of making a composite self-standing substrate in Example 1 according to the invention;

FIG. 4 is a schematic cross sectional view showing an LED epitaxial layer in Example 2 according to the invention;

FIG. 5 is a schematic cross sectional view showing an LED epitaxial layer in Comparative Example; and

FIGS. 6A to 6F are schematic cross sectional views showing a method of making a composite self-standing substrate in Example 3 according to the invention;

### DETAILED DESCRIPTION OF THE PREFERRED EMBODIMENTS

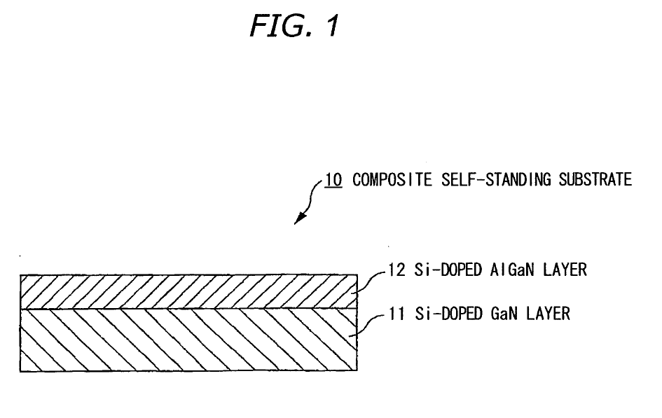

FIG. 1 is a cross sectional view showing a composite self-standing substrate in the preferred embodiment according to the invention.

The composite self-standing substrate 10 comprises a Si-doped GaN layer 11 and a Si-doped AlGaN layer 12 formed on the Si-doped GaN layer 11. The surface of the Si-doped AlGaN layer 12 and the back surface of the Si-doped GaN layer 11 are flattened by lapping, polishing, grinding etc. Meanwhile, the detailed description below is related not only to the embodiment concerning the Si-doping but also to all the other embodiments.

### Self-Standing Substrate

Herein, a self-standing substrate means a substrate that is capable of holding its shape by itself and has a sufficient strength for handling. To provide such a strength, the thickness of self-standing substrate is preferably 200 μm or more.

### Size of Substrate

The GaN self-standing substrate of the embodiment has a circular form with a diameter of 50 mm or more and preferably a thickness of 200 μm or more. Light emitting devices, especially, LED's are a versatile device used for civilian goods, and, therefore, they need to satisfy amass productivity so that they can be practically used and prevailed. If the substrate has a diameter greater than 50 mm, it can be easy applied to the mass production process since a mass-production processing apparatus has been already developed for GaAs substrates. The reason why the substrate needs a thickness greater than 200 μm is that, if less than 200 μm in thickness, the substrate may crack frequently when being handled by a pin set etc.

### Dislocation Density of Substrate

It is desired that the dislocation density at the surface of the substrate is less than 1×10⁸ cm⁻². It is known that the dislocation from the substrate is propagated into the epitaxial growth layer grown on the substrate. The dislocation of the epi-layer will degrade the device characteristics to lower the reliability. Thus, it is desired that, in substrates for short-wavelength and high-output LED or LD, the dislocation density of the epi-layer is less than 1×10⁸ cm⁻², in order not to degrade the device characteristics to keep the reliability.

### Conductivity Type and Carrier Concentration of Substrate

The conductivity type of the substrate should be controlled suitably according to the target device, and is not to be determined uniformly. The conductivity type of the substrate can be rendered n-type by doing Si, S, O etc. or p-type by doping Mg, Zn etc. Also, the absolute value of the carrier concentration of the substrate should be controlled suitably according to the target device, and is not to be determined uniformly.

### First Layer in Substrate

The first layer of the substrate (=the Si-doped GaN layer 11 in FIG. 1) is rendered a GaN layer since it can be easy epitaxially grown and it can be easy crystallized with a large diameter and a thick thickness. It is desired that the first layer of the substrate has a Ga facet in (0001) direction on the surface. This is because the GaN crystal has a strong polarity and the Ga facet is more stable than its N facet (=nitrogen facet) in chemical and thermal aspects.

### Carrier Concentration of First Layer

In case of fabricating a device with an electrode formed on the back surface, it is desirable to use a conductive substrate to which its back surface electrode can be contacted easy. Thus, it is desirable that the first layer of the substrate has a carrier concentration of 5×10¹⁷ cm⁻³ or more.

### Second Layer in Substrate

The second layer of the substrate (=the Si-doped AlGaN layer 12 in FIG. 1) can be formed in arbitrary composition as represented by AlₓGa₁₋ₓN, where 0<x≦1. It is desired that the second layer of the substrate is grown continuously in the same reactor as the underlying first layer 11. This is not only because the time required for the growth can be shortened, but also because the generation of oxide film between the first layer and the second layer can be prevented, so that the generation of defects in the second layer can be suppressed as well as the generation of an electrical barrier layer therebetween.

The second layer may be formed by increasing gradually Al ratio in AlₓGa₁₋ₓN, where 0<x≦1, from the interface between the first layer and it so that the composition varies continuously.

### Carrier Concentration of Second Layer

It is desirable that the second layer (=the Si-doped AlGaN layer 12 in FIG. 1) has a high carrier concentration not to increase the drive current. Although it depends on the thickness of the second layer, it is desirable that it has a carrier concentration of 1×10¹⁷ cm⁻³ or more.

### Thickness of Second Layer

In order that a layer with a lattice constant of AlₓGa₁₋ₓN is uniformly on the entire surface of the substrate, it is necessary to form the second layer as a continuous film and to render the lattice of the second layer not strained by being influenced by the lattice constant of the underlying first layer. To that end, it is desirable that the second layer has a thickness of 100 nm or more. If less than 100 nm, even when having the composition of AlₓGa₁₋ₓN on the surface, there may be partially generated a region with strained lattice constant. If AlₓGa₁₋ₓN is epitaxially grown thereon, a new defect can be thereby generated in the epitaxial layer due to the lattice mismatch.

On the other hand, it is desirable that the second layer has a thickness of 100 μm or less. If more than 100 μm, there may be generated a fluctuation in composition of the second layer so that the reproducibility of the substrate characteristics among devices will deteriorate, and the thermal resistance in the thickness direction of the substrate will increase to lower the heat radiation property of the device fabricated using the substrate.

### Surface of Second Layer

In general, there are many large uneven parts such as hillocks or microscopic uneven parts which are assumed to be generated by step bunching, on the surface of the as-grown second layer (=the Si-doped AlGaN layer 12 in FIG. 1). Thus, the surface is flattened by polishing, lapping, grinding etc. The flattening is intended not only to remove factors to render uneven the morphology, thickness, composition of an epi-layer grown thereon, but also to improve the device production yield without reducing the processing precision of photolithography in the device fabrication process.

### Back Surface of First Layer

The back surface of the first layer (=the Si-doped GaN layer 11) of the substrate is also flattened by polishing, lapping, grinding etc. The flattening of the back surface is intended to improve the contact between the substrate and the susceptor when growing the epi-layer on the substrate. If the back surface of the substrate is not in uniform contact with the susceptor, the thermal conduction from the susceptor becomes uneven and, thereby, the in-plane substrate temperature during the epi-growth will be uneven. Since the in-plane unevenness of the substrate temperature causes unevenness in the crystal growth rate, composition and impurity concentration, the epi-layer with in-plane uniform characteristics cannot be obtained. Although apparatuses for the epi-growth include a face-down type in which the back surface of the substrate is not in contact with the susceptor, even the face-down type uses generally a flat plate called uniform heating plate disposed on the back surface of the substrate. If distance between the back surface of the substrate and the uniform heating plate is uneven, the unevenness in temperature will be generated which causes the unevenness in device characteristics. The back surface only has to be flattened such that it is in close contact with the susceptor during the epi-growth. Therefore, it does not always have to be mirror-finished. For example, it can be a lapped surface, a ground surface or the lapped or ground surface being treated by etching etc. to remove a strain.

### Method of Making the Composite Self-Standing Substrate

The composite self-standing substrate of the embodiment can be obtained by growing the GaN layer and the AlₓGa₁₋ₓN layer single crystals on the hetero-substrate, and then removing the hetero-substrate by separation. The GaN layer and the AlₓGa₁₋ₓN layer single crystals are desirably grown by HVPE (hydride vapor phase epitaxy). This is because the HVPE is high in crystal growth rate so that it is suitable for the substrate fabrication in which a thick film is needed to grow.

### Structure of HVPE Reactor

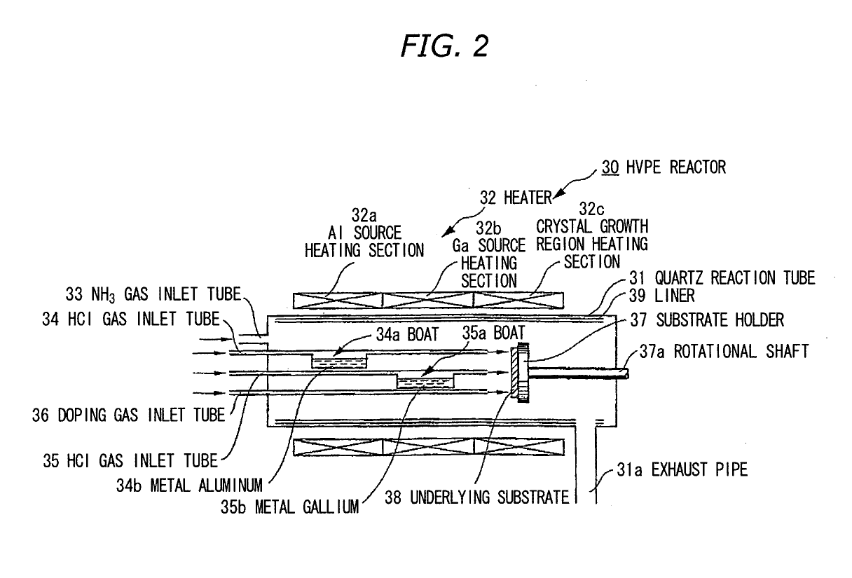

FIG. 2 shows an example of HVPE reactor to be used in the embodiment.

The HVPE reactor 30 is of hot-wall type in which a heater 32 is disposed outside a quartz reaction tube 31 horizontally installed to heat the tube. On the left side (upstream side) of the quartz reaction tube 31, an NH₃ gas inlet tube 33 to introduce NH₃ gas as group V source, an HCl gas inlet tube 34 to introduce HCl gas to form AlCl₃ as group III source, an HCl gas inlet tube 35 to introduce HCl gas to form GaCl as group III source, and a doping gas inlet tube 36 to introduce dopant gas to control the conductivity type are provided. The HCl gas inlet tube 34 is made of alumina, and it is midway provided with a boat 34a of pyrolytic graphite (PG), in which metal aluminum 34b is accommodated. The HCl gas inlet tube 35 is made of quartz, and it is midway provided with a boat 35a of quartz, in which metal gallium 35b is accommodated.

On the right side (downstream side) of the quartz reaction tube 31, a substrate holder 37 for mounting an underlying substrate 38 thereon is supported by a rotational shaft 37a, around which the substrate holder 37 can be rotated.

The heater 32 comprises three zones of an Al source heating section 32a to heat a part corresponding to the boat 34a where the metal aluminum 34b is accommodated, a Ga source heating section 32b to heat a part corresponding to the boat 35a where the metal gallium 35b is accommodated, and a crystal growth region heating section 32c to heat a part corresponding to the underlying substrate 38.

On the inner wall of the quartz reaction tube 31, a liner 39 of pyrolytic boron nitride (PBN) is disposed to prevent the erosion of the quartz which may react with the Al source during the crystal growth, and to prevent the cracking of the reaction tube which may crack due to the difference in thermal expansion coefficient between the deposited material in the growth and the quartz during the cooling step of the reactor. An exhaust pipe 31a is disposed at an end of the quartz reaction tube 31 on the downstream side thereof.

### Growth Method

A method of growing sequentially the GaN layer and the AlGaN layer on the underlying substrate 38 by using the HVPE reactor 30 will be explained below.

At first, the underlying substrate 38 of sapphire etc. is placed on the substrate holder 37, and the metal-aluminum 34b and the metal gallium 35b are charged into the boats 34a and 35a, respectively. Then, the Al source heating section 32a and the Ga source heating section 32b are heated to 500° C. and 800° C., respectively, whereby the metal aluminum 34b and the metal gallium 35b are melted. The crystal growth region heating section 32c is heated to 1000° C. Then, NH₃ gas as group V source is introduced from the NH₃ gas inlet tube 33, and HCl gas to produce the group III source is introduced from the HCl gas inlet tube 35. Meanwhile, for the control of the reaction, the HCl gas and NH₃ gas as source gas are introduced mixed with a carrier gas such as H₂ gas.

In the HCl gas inlet tube 35, the HCl gas is midway contacted with the metal gallium 35b being melted to conduct a reaction: Ga+HCl→GaCl+(½)H₂, whereby GaCl gas is generated.

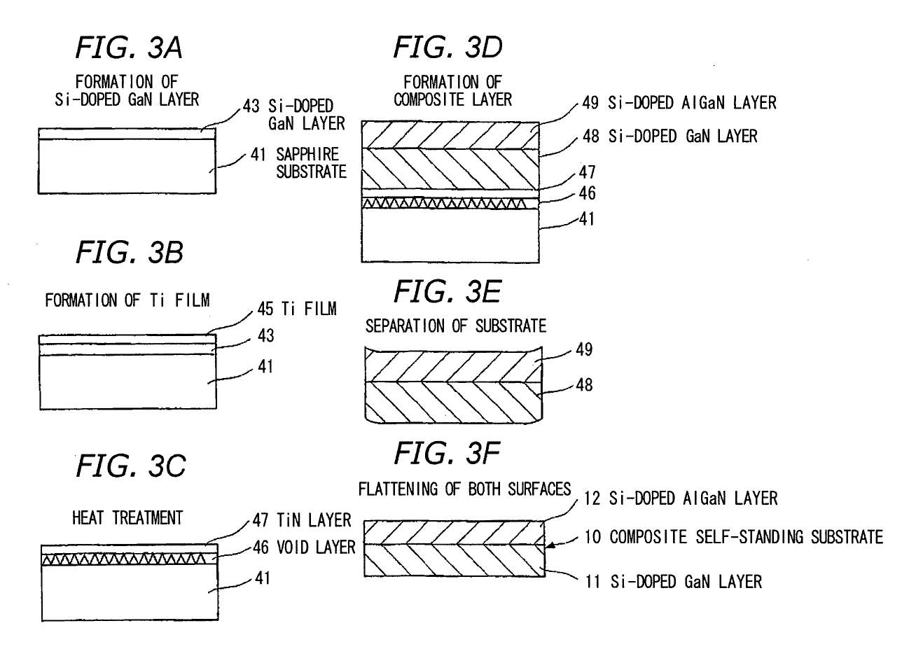

The mixed gas of the GaCl gas thus generated and the H₂ carrier gas and the mixed gas of the NH₃ and the H₂ carrier gas are carried in the direction of arrows (in FIG. 3) in the space of the quartz reaction tube 31. On the underlying substrate 38 placed on the substrate holder 37, a reaction: GaCl+NH₃→GaN+HCl+H₂ is conducted, whereby the GaN is deposited on the underlying substrate 38. The gases introduced into the quartz reaction tube 31 are sent through the exhaust pipe 31a downstream to a detoxification facility, where they are detoxified by a treatment, and discharged in the air.

Meanwhile, a dopant can be doped into the GaN layer by introducing the dopant gas from the doping gas inlet tube 36 during the formation of the GaN layer.

Then, the NH₃ gas as group V source is introduced from the NH₃ gas inlet tube 33, and the HCl gas to produce the group III source is introduced from the HCl gas inlet tube 34. Meanwhile, for the control of the reaction, the HCl gas and NH₃ gas as source gas are introduced mixed with a carrier gas such as H₂ gas.

In the HCl gas inlet tube 34, the HCl gas is midway contacted with the metal aluminum 34b being melted to conduct a reaction: Al+3HCl→AlCl₃+( 3/2)H₂, whereby AlCl₃ gas is generated.

In the HCl gas inlet tube 35, the HCl gas is midway contacted with the metal gallium 35b being melted to conduct a reaction: Ga+HCl→GaCl+(½)H₂, whereby GaCl gas is generated.

The mixed gas of the AlCl₃ gas thus generated and the H₂ carrier gas and the mixed gas of the NH₃ and the H₂ carrier gas are carried in the direction of arrows (in FIG. 3) in the space of the quartz reaction tube 31. On the underlying substrate 38 placed on the substrate holder 37, a reaction: AlCl₃+GaCl+(½H₂)+NH₃→AlGaN+4HCl is conducted, whereby the AlGaN is deposited on the underlying substrate 38. The gases introduced into the quartz reaction tube 31 are sent through the exhaust pipe 31a downstream to a detoxification facility, where they are detoxified by a treatment, and discharged in the air.

### Separation Method

After the GaN layer and the AlGaN layer are grown on the underlying substrate 38, the underlying substrate 38 is separated to provide the composite self-standing substrate 10 comprising the GaN layer 11 and the AlGaN layer 12 as shown in FIG. 1. The separation can be conducted by VAS (void-assisted separation) method. The VAS method is excellent in that it allows the separation of a large-diameter substrate with a good reproducibility, and that it allows the formation of a GaN-based self-standing substrate with a low dislocation density and uniform characteristics.

### Effects of the Embodiment

(1) AlGaN is more difficult to grow than GaN. Therefore, the AlGaN has many crystal defects and is low in crystalline quality. However, in this embodiment, since the AlGaN is epitaxially grown on the high-quality GaN crystal with few defects, the crystalline quality of the AlGaN can be enhanced due to that of the underlying GaN layer.

(2) AlGaN is a mixed crystal of three elements and it is, therefore, difficult to control the composition of AlGaN as compared to two-element compounds, i.e., it is difficult to grow continuously a thick layer with uniform composition. However, in this embodiment, since the thin AlGaN layer is grown on the uniform GaN layer, the composition of the AlGaN can be uniformed. As a result, the device can be produced with a good reproducibility while suppressing the dispersion of characteristics between the wafers.

(3) The growth rate of AlGaN is difficult to increase without damaging the crystalline quality since AlGaN is more difficult to grow than GaN. However, in this embodiment, since the AlGaN only has to be grown on the surface of GaN grown at a high speed, the total growth time required can be shortened to improve the productivity significantly.

(4) In AlGaN as a three-element mixed crystal, even when few % of Al is added into GaN, the thermal conductivity will be reduced to about 1/10 so that the heat radiation property through such a substrate will deteriorate in a device with large heat generation such as a high-output light emitting device and a power device. Therefore, the AlGaN mixed crystal substrate will not be employed even if it is advantageous in lattice matching. However, in this embodiment, the AlGaN layer with low thermal conductivity is located only at the very thin surface portion of the substrate. Therefore, the substrate of the embodiment can have substantially the same thermal conductivity as the GaN substrate while it has the lattice constant of AlGaN at the surface thereof.

(5) Aluminum chloride as a source used to grow the AlGaN by HVPE may react with the quartz member composing the reactor depending on the growth conditions, and the quartz member may be eroded. However, in this embodiment, since the growth of the AlGaN is minimized, the erosion can be suppressed significantly.

(6) When the AlGaN is in a separate process formed on the GaN, native oxide film will be generated since the GaN is once exposed into the air, or the growth surface may be not clean due to a contamination during the handling. Further, since the GaN surface is subjected to a rising and falling temperature cycle, it may be denatured by heat. As a result, a number of cracks may be generated in the AlGaN crystal layer. However, in this embodiment, since the GaN layer and the AlGaN layer can be sequentially grown in the same reactor without changing the growth temperature significantly, the composite self-standing substrate can be obtained without cracks and with the GaN/AlGaN interface kept clean.

(7) In this embodiment, the AlGaN can be epitaxially grown on the GaN, like the epitaxial growth method on the GaN substrate which is practically used for the epitaxial growth of a device structure, since the thick GaN layer as a base is formed previously. Also, the conventional method for device fabrication process can be without change applied to the substrate of this embodiment. The cracking of the substrate will be prevented. Thus, a device structure can be easy formed on the AlGaN substrate with a good reproducibility.

### EXAMPLE 1

By using a process as shown in FIGS. 3A to 3F, the composite self-standing substrate 10 in FIG. 1 is fabricated.

First, on a C-face sapphire substrate 41 with a diameter of 2 inches, a Si-doped GaN layer 43 is grown 0.5 μm through a 20 nm thick low-temperature grown GaN buffer layer (not shown) by MOVPE (FIG. 3A). The growth conditions are atmospheric pressure, substrate temperature of 600° C. during the growth of the buffer layer, and substrate temperature of 1100° C. during the growth of the epi-layer. The group III source used is trimethylgallium (TMG), the group V source used is ammonium (NH₃), and the dopant is monosilane. The carrier gas is a mixed gas of hydrogen and nitrogen. The growth rate of the crystal is set to be 4 μm/h. The carrier concentration of the epi-layer is set to be 2×10¹⁸ cm⁻³.

Then, on the Si-doped GaN layer 43, a metal Ti film 45 is deposited 20 nm thick (FIG. 3B). The substrate thus obtained is placed in an electric oven, where it is thermally treated at 1050° C. for 20 min. in H₂ gas flow containing 20% of NH₃. As a result, a part of the GaN layer 43 is etched to generate a high-density void layer 46, and the Ti film 45 is nitrided into TiN layer 47 on the surface of which microscopic submicron holes are formed at high density (FIG. 3C).

Then, the substrate is placed in the HVPE reactor as shown in FIG. 2, where a GaN layer 48 is grown 450 μm thick by using a supply gas which contains a source gas of 8×10⁻³ atm GaCl and 4.8×10⁻² atm NH₃ in a carrier gas (FIG. 3D). The carrier gas used is N₂ gas containing 5% of H₂. The growth conditions of the GaN layer 48 are atmospheric pressure, and substrate temperature of 1000° C. Further, in the process of the GaN crystal growth, silicon is doped by supplying dichlorosilane as a doping source gas.

After the growth of GaN is completed, an AlGaN layer 49 is grown 150 μm thick by using a supply gas which contains a source gas of 8.0×10⁻³ atm GaCl, 2.2×10⁻³ atm AlCl₃ and 4.8×10⁻² atm NH₃ in a carrier gas (FIG. 3D). The carrier gas is N₂ gas during the growth of the AlGaN layer 49 and silicon is doped by supplying dichlorosilane as a doping source gas.

After the growth of AlGaN is completed, the GaN layer 48 and the AlGaN layer 49 are automatically separated at the void layer 46 from the sapphire substrate 41 during the cooling process of the HVPE reactor. Thus, the composite self-standing substrate can be obtained.

The composite self-standing substrate obtained is slightly convex warped on the back side, and is formed slightly concave on the top side according to the warping on the back side (FIG. 3E). However, no significant defect such as a crack is observed.

Then, both surfaces of the composite self-standing substrate obtained are flattened on a metal plate by lapping with diamond slurry, and the composite self-standing substrate 10 can be formed. Further, the top surface is mirror-polished with finer diamond slurry. The amount of removal by the flattening is about 70 μm and about 125 μm on the top side and back side, respectively (FIG. 3F).

The thickness of the substrate is measured 405±2 μm at any points thereof by a dial gauge. In the substrate thus obtained, the GaN layer 11 is 325 μm thick and the AlGaN layer 12 on the top side is 80 μm thick.

The aluminum composition of the AlGaN layer 12 at the top surface of the substrate is measured 0.2 by X-ray diffraction. By (0001) diffraction of the AlGaN layer 12, the half-value width of the X-ray rocking curve is measured 165 sec. In order to evaluate the dislocation density of the substrate, the Si-doped GaN layer is epitaxially grown 1 μm on AlGaN layer 12 by MOVPE and the density of dark spots on its surface is evaluated by cathode luminescence. As a result, the values are 4.5×10⁶ cm⁻² at the center of the composite self-standing substrate 10 and 5.2×10⁶ cm⁻² as an average of in-plane nine points. Further, the silicon concentrations of the AlGaN layer 12 and the GaN layer 11 of the substrate are measured 7×10¹⁷ cm⁻³ and 2×10¹⁸ cm⁻³, respectively, by SIMS.

### EXAMPLE 2

The surface of the composite self-standing substrate obtained in Example 1 is dry-etched about 1 μm thick in order to remove a process strain layer thereof. Then, on this substrate, a blue LED epitaxial layer is grown by low pressure MOVPE.

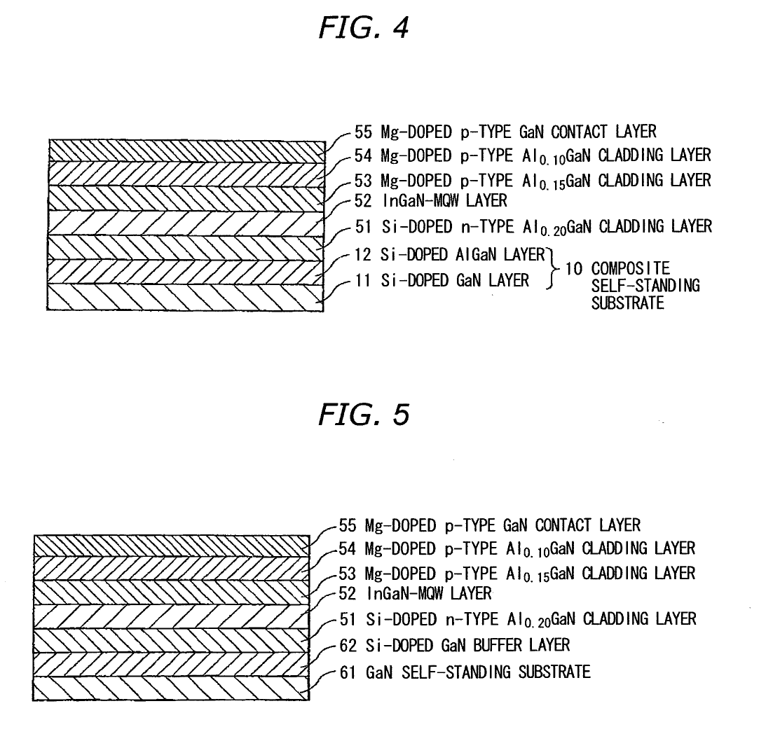

FIG. 4 shows the blue LED epitaxial structure. The blue LED epitaxial structure comprises, grown on the composite self-standing substrate 10, a Si-doped n-type Al_{0.20}GaN layer 51, an InGaN-MQW (with 3 periods) layer 52, a Mg-doped p-type Al_{0.15}GaN cladding layer 53, a Mg-doped p-type Al_{0.10}GaN cladding layer 54, and a Mg-doped p-type GaN layer 55.

Then, photoluminescence (PL) of the LED epitaxial layer is measured. Although the PL emission intensity has an in-plane dispersion of 12%, the dispersion is sufficiently small as compared to Comparative Example as explained below.

### COMPARATIVE EXAMPLE

As shown in FIG. 5, the blue LED epitaxial structure of Comparative Example comprises, grown-on the GaN self-standing substrate 61 that only a GaN layer is grown, the Si-doped GaN buffer layer 62 formed as in Example 2, and the LED structure formed as in Example 2.

In measuring the photoluminescence (PL) emission intensity, it has an in-plane dispersion of 25%. Also, the average of the emission intensities is reduced about 15% as compared to Example 2.

### EXAMPLE 3

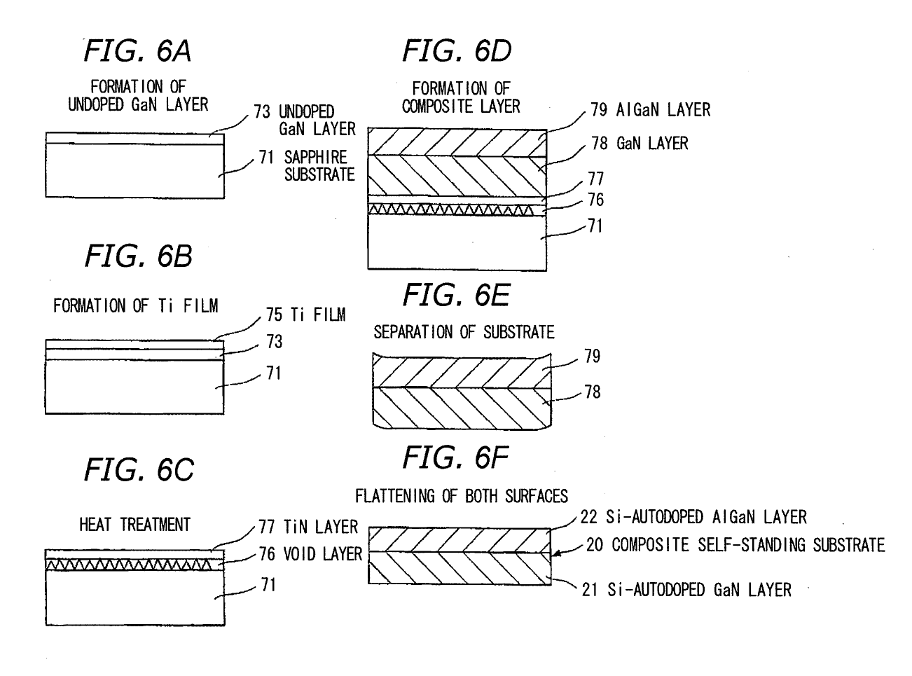

By using a process as shown in FIGS. 6A to 6F, a composite self-standing substrate 20 in another embodiment is fabricated.

First, on a commercially available single-crystal C-face sapphire substrate 71 with an off angle of 0.25° in m-axis direction and with a diameter of 2.5 inches, an undoped GaN layer 73 is grown 300 nm by MOVPE (FIG. 6A). The growth conditions are atmospheric pressure, and substrate temperature of 1100° C. during the growth of the epi-layer. The group III source used is trimethylgallium (TMG), and the group V source used is ammonium (NH₃). The carrier gas is a mixed gas of hydrogen and nitrogen. The growth rate of the crystal is set to be 4 μm/h.

Then, on the undoped GaN layer 73, a metal Ti film 75 is deposited 25 nm thick (FIG. 6B). The substrate thus obtained is placed in the electric oven, where it is thermally treated at 1000° C. for 25 min. in H₂ gas flow containing 20% of NH₃. As a result, a part of the GaN layer 73 is etched to generate a high-density void layer 76, and the Ti film 75 is nitrided into TiN layer 77 on the surface of which microscopic submicron holes are formed at high density (FIG. 6C).

Then, the substrate is placed in the HVPE reactor as shown in FIG. 2, where a GaN layer 78 is grown 400 μm thick (FIG. 6D) The growth conditions of the GaN layer 78 are atmospheric pressure, and substrate temperature of 1040° C. The source gases are GaCl and NH₃. The carrier gas is nitrogen gas containing 5% of hydrogen at the initial stage of the growth, and the amount of hydrogen gas mixed is reduced gradually to zero from the time when the GaN is about 120 μm grown. The crystal growth rate in the HVPE is about 120 μm/h. From the time when the GaN is 400 μm grown, the amount of GaCl introduced in the reactor is reduced gradually and the amount of the AlCl₃ is increased gradually so that AlCl₃ becomes 15% (in gas phase ratio) relative to GaCl finally. During this process, the amount of NH₃ is not changed and the V/III ratio is kept to be 12 constantly. Thus, while the AlGaN is grown about 20 μm, the composition is continuously changed from GaN to AlGaN, and then an AlGaN layer with a constant composition is further grown 90 μm to provide AlGaN layer 79 with about 110 μm in total thickness (FIG. 6D).

After the growth of AlGaN is completed, the GaN layer 78, the AlGaN layer 79 are automatically separated at the void layer 76 from the sapphire substrate 71 during the cooling process of the HVPE reactor (FIG. 6E).

After the growth, on the surface of the AlGaN layer 79, no significant defect such as a crack is observed, and a clean morphology is provided to be evaluated a mirror surface by human eyes.

Then, the back surface of the composite self-standing substrate obtained is flattened by a grinding machine with diamond wheel, and, in order to remove the process strain layer, the back surface is slightly etched in a heated solution of potassium hydroxide. Further, the outer diameter of the substrate is shaped into φ50.8 mm by a chamfering machine. The top surface is flattened on a metal plate by lapping with diamond slurry, and is mirror-polished with finer diamond slurry. The amount of removal by the flattening is about 80 μm and about 100 μm on the top side and back side, respectively. Thus, the composite self-standing substrate 20 is obtained (FIG. 6F).

The thickness of the substrate is measured 330±2 μm at any points thereof by a dial gauge. In the substrate thus obtained, the GaN layer 21 is 300 μm thick, and the AlGaN layer 22 is 30 μm thick.

The aluminum composition of the AlGaN layer 22 at the top surface of the substrate is measured 0.15 by X-ray diffraction. By (0001) diffraction of the AlGaN layer, the half-value width of the X-ray rocking curve is measured 125 sec. In order to evaluate the dislocation density of the substrate, the Si-doped GaN layer is epitaxially grown 1 μm on the substrate by MOVPE and the density of dark spots on its surface is evaluated by cathode luminescence. As a result, the values are 4.2×10⁶ cm⁻² at the center of the composite self-standing substrate 20 and 4.9×10⁶ cm⁻² as an average of in-plane nine points.

Further, the silicon concentrations of the AlGaN layer 22 and the GaN layer 21 of the substrate are measured 5×10¹⁷ cm⁻³ and 9×10¹⁷ cm⁻³, respectively, by SIMS. It is assumed that such high silicon concentrations are brought by being autodoped from the quartz component of the reactor in the process of HVPE although any doping gas is not flown thereinto.

### Other Embodiments

Although the AlGaN is grown by HVPE in the above embodiments or Examples, it can be grown by MOVPE as separate process.

At the initial or middle step of the crystal growth, the known ELO method using a SiO₂ mask etc. may be used which allows the generation of a number of uneven parts on the crystal growth interface.

Although the sapphire substrate is used as the underlying substrate in the above embodiments or Examples, the other substrates, which are reported as a GaN-based epitaxial layer growth substrate, such as GaAs, Si, ZrB₂, ZnO etc. can be all used similarly.

Although the Si-doped substrate is exemplified in the above embodiments or Examples, the composite self-standing substrate may be undoped or doped with a suitable dopant such as Mg, Fe, S, O, Zn, Ni, Cr, Se etc.

Although the AlGaN layer grown on the GaN layer is exemplified in the above embodiments or Examples, the AlGaN layer may be grown on an AlN layer instead of the GaN layer. In this case, although the thermal conductivity is expected to be further enhanced than the case using the GaN layer, it is difficult to fabricate it.

In modification, a self-standing substrate comprising InGaN, or a self-standing substrate with a multilayer structure comprising GaN, AlGaN, InGaN can be fabricated.

Although the invention is applied to the group III-V nitride-based semiconductor self-standing substrate, it can be applied to a group III-V nitride-based epitaxial substrate (template) with hetero-underlying substrate such as sapphire.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

What is claimed is:

1. A group III-V nitride-based semiconductor substrate, comprising:
a first layer comprising GaN single crystal; and
a second layer formed on the first layer, the second layer comprising group III-V nitride-based semiconductor single crystal represented by AlₓGa₁₋ₓN, where 0<x≦1,
wherein a top surface and a back surface of the substrate are flattened.

2. The group III-V nitride-based semiconductor substrate according to claim 1:
the second layer comprises the group III-V nitride-based semiconductor single crystal represented by AlₓGa₁₋ₓN, where 0<x≦1, whose Al ratio increasing continuously from an interface of the first layer and the second layer.

3. The group III-V nitride-based semiconductor substrate according to claim 1, wherein:
the substrate is in circular form with a diameter of not less than 50 mm and a thickness of not less than 200 μm.

4. The group III-V nitride-based semiconductor substrate according to claim 1, wherein:
the substrate comprises a dislocation density of not more than 1×10⁸ cm⁻² on its surface.

5. The group III-V nitride-based semiconductor substrate according to claim 1, wherein:
the AlₓGa₁₋ₓN layer, where 0<x≦1, comprises a thickness of not less than 100 nm.

6. The group III-V nitride-based semiconductor substrate according to claim 1, wherein:
the AlₓGa₁₋ₓN layer, where 0<x≦1, comprises a thickness of not less than 100 nm and not more than 100 μm.

7. A method of making a group III-V nitride-based semiconductor substrate, comprising the steps of:
growing a group III-V nitride-based semiconductor film on a hetero-substrate and then depositing a metal film thereon;
heating the hetero-substrate with the metal film in an atmosphere containing hydrogen gas or hydride gas to form a void in the group III-V nitride-based semiconductor film;
growing a first layer comprising a GaN single crystal thereon;
further growing thereon a second layer comprising a group III-V nitride-based semiconductor single crystal represented by AlₓGa₁₋ₓN, where 0<x≦1;
removing the hetero-substrate while leaving the first layer and the second layer to provide the group III-V nitride-based semiconductor substrate; and
flattening a top surface and a back surface of the substrate.

8. The method according to claim 7, wherein:
the first layer and the second layer are continuously grown in a same reactor.

9. The method according to claim 7, wherein:
the first layer and the second layer are grown by HVPE.
